(19) United States
(12) Patent Application Publication
(10) Pub. No.: US 2009/0097200 A1
(43) Pub. Date: Apr. 16, 2009

(54) MODULAR BLADE FOR PROVIDING SCALABLE MECHANICAL, ELECTRICAL AND ENVIRONMENTAL FUNCTIONALITY IN THE ENTERPRISE USING ADVANCEDTCA BOARDS

(76) Inventors: Viswa Sharma, San Ramon, CA (US); William Chu, Elmsford, NY (US)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(21) Appl. No.: 12/101,739

(22) Filed: Apr. 11, 2008

Related U.S. Application Data
(60) Provisional application No. 60/911,244, filed on Apr. 11, 2007.

(51) Int. Cl. H05K 7/00; H05K 7/20

(52) U.S. Cl. 361/688; 361/752

(57) ABSTRACT

A standards-based server blade arrangement is provided wherein individual circuit boards may be compliant with a first industry driven or other standard and housed within an enclosure configured such that one aspect of the enclosure provides each circuit board with a scalable, mechanical, electrical and environmental functionality required for that circuit board to comply with the first industry driven or other standard and a second aspect of the enclosure allows the enclosure to comply with a second industry driven or other standard.

### RELATED APPLICATION

This application claims the benefit of U.S. Provisional Application No. 60/911,244 filed Apr. 11, 2007, which is hereby fully incorporated herein by reference

### FIELD OF THE INVENTION

The present invention relates generally to telecommunications, networking and computer equipment and specifically, but not exclusively, to a modular Advanced Telecom Computing Architecture based server blade arrangement that is interoperable and interchangeable with conventional server blades in the enterprise setting and that is configurable into an interconnected structure capable of providing scalable mechanical, electrical and environmental functionality.

### BACKGROUND OF THE INVENTION

One of the products that has deep penetration into the enterprise information technology infrastructure is the ubiquitous multi-tiered modular rack supporting a group of modular chassis that in turn are capable of meeting, either singly or in combination with other chasses, the data communication, computing and telecommunication needs of the enterprise. Typically, racks provide each chassis access to network connections and electrical power. A typical chassis may contain components and interconnecting devices such as printed circuit boards, interconnecting wires, electronic and mechanical modules and other components arranged to form a system such as a server. Each chassis functions to provide an environment relatively free from excessive heat, shock, vibration and/or dust for the computer system. Groups of these computer systems are interconnected to form electronic applications, such as server farms that serve the networking needs of business organizations. Prior art practice has found it advantageous to standardize rack dimensions in order to house standardized chasses. For example, a 19-inch rack is standardized (EIA 310-D, IEC 60297 and DIN 41494 SC48D) for mounting various electronic modules in a “stack”, or rack, 19 inches (482.6 mm) wide. Chasses designed to be placed in a rack are designated as rack-mount, a rack mounted system, a rack mount chassis, subrack, or occasionally, simply shelf. A 1 U tall subrack (also referred to as a “pizza box” or “slab”) chassis is available in various form factors such as 19 inches wide by 24, 30, 36 and 48 inches deep. A “U” is the measured height of a chassis case where 1 U=1.75 inches or 44.45 mm. 19 inches or 482.6 mm is the width of the front plate, 17.75 inches or 450.85 mm the space left for the chassis (the rails take up 0.625 inches or 15.875 mm on each side). Each chassis may house a separate computer or server, for example, having one or more CPUs. In particular, the small form factor allows for a large number of servers to be vertically stacked, typically with up to 47 U in each rack. The modular nature of each such chassis allows for a given server system to be swapped out of the network and the rack without interfering with the operation of other computer systems.

Conventional server blades while conforming to some industry specification in terms of the external form factor (geometry) so they can be mounted on a standardized rack or in terms of the input/output (I/O), power and other interfaces they present to the environment external to the blade so as to be compatible for cooperative operation with the rack and other external devices on and off the rack. Generally, such blades embody proprietary, monolithic electro-mechanical dedicated hardware and software solution within that external form factor that are designed for a particular application or set of applications and made available in a packaging that typically conforms to an industry-wide standard. The internal geometry and layout is relatively fixed in that they cannot be easily configured to suit the needs of an alternate application except perhaps by swapping out the blade with a blade specifically designed for the alternate application. Conventional blade architecture generally provides both, the electronic circuitry—i.e. devices, components, firmware and software, that actually effectuate a desired application, as well as the auxiliary modules/subsystems such as the cooling units, the controllers, the management software and firmware and so forth that play a supporting role in effectuating the desired application. Changing out a conventional server module does not generally allow the retention and reuse of the auxiliary modules with the replacement blade. Nor can the dedicated hardware solution available in a particular sized chassis be easily adapted to a different sized chassis targeted for operation in a different server environment. Very often the replacement blade is from the same manufacturer or vendor when several blades need to operate cooperatively because of the difficulties of integrating blades from different vendors in the same rack or enterprise. Accordingly, it would be advantageous to provide a blade, targeted to the enterprise class server technology segment, that can be constructed from commercial-off-the-shelf (COTS) technology and that can be swapped out, if needed, for another blade also based on COTS technology but capable of delivering a different application(s) without having to discard or replace the auxiliary modules/subsystems that are oftentimes associated with and integrated into the blade.

There has been a widespread shift from the historic telecommunications business model which fostered low unit volume, relatively high price proprietary system architectures to standards-based solutions built using COTS technology. One of the business drivers for this shift is the need for flexibility to respond to a rapidly changing network infrastructure and the need to keep operating and capital expenditures low. Catalyzing this shift are standards based technologies that adhere to specifications defined by industry sponsored standards making bodies. For example, the Advanced Telecom Computing Architecture (or AdvancedTCA™ hereinafter “ATCA”) based platform can be used by both, suppliers and end-users to construct ATCA standard-compliant solutions.

The ATCA specification is a series of industry standards that define scalable, standardized platform architecture to extend COTS to a broad spectrum of products available from component vendors. ATCA compliant components and systems embody interoperable ATCA technology such as physical format, system management and software designed to deliver cost effective, reduced time-to-market, off-the-shelf solutions that can be incorporated into products ranging from high-availability, carrier-grade telecom, storage, and computing applications. ATCA is sponsored by the PCI (Personal Computer Interconnect)—Industrial Computer Manufacturers Group (PICMG®), a major industry standards body.

The ATCA Base Specification, PIGMG 3.0 Revision 2.0, ratified in Dec. 30, 2002 (hereinafter “the ATCA specification”), defines an open electromechanical architecture of a modular platform that may be constructed from commercial off-the-shelf components. The electromechanical architecture encompasses the rack and shelf (chassis) mechanical form factors, power parameters, cooling characteristics, core backplane fabric interconnects and system management architecture to enable the construction of a modular platform that is capable of receiving a multiplicity of ATCA compliant modular plug-in circuit boards (ATCA Carrier cards). The ATCA compliant modular plug-in circuit boards feature an open electromechanical architecture also defined by the ATCA specification. The ATCA base specification together with other associated specifications define multiple fabric connections and support multiple protocols for control and data plane communications including Ethernet, Fibre Channel, InfiniBand, StarFabric, PCI Express, and RapidIO®.

The AdvancedTCA specification defines the requirements for the ATCA circuit boards when plugged into ATCA circuit board slots provided in the ATCA backplane to form an ATCA system or shelf. The ATCA 3.0 base specification defines a power budget of 200 Watts (W) per board. Power is delivered to the frame by dual redundant −48 VDC feeds. Local DC-DC conversion is accomplished per board. Redundant local power feeds are normally attached through either diode OR'ed connections to a single on-board DC-DC converter or via on-board dual redundant load sharing DC-DC converters. The ATCA backplane includes power distribution circuitry that distributes the dual redundant power feeds from the two power entry modules to the circuit boards plugged into the ATCA backplane such that as much as 200 Watts is dissipated per single-slot ATCA circuit board in addition to the power consumption requirements of other ATCA-specific shelf components. Circuit boards may occupy more than one circuit board slot to receive more than the maximum 200 Watts (W) per board. Under the PICMG 3.0 specification, each board is supplied with dual −48 VDC feeds. Each feed remains isolated and is fed individually to each board slot through the backplane. There are two basic methods for combining the dual redundant feeds. One method combines the two feeds through diode OR'ing and delivers the combined single feed to DC-DC converters. If either feed fails, all power shall be delivered by the surviving feed. The second method is to direct each of the two feeds to its own DC-DC converter. The outputs of the converters are then combined to provide power to the rest of the power supply circuits.

In order to support power dissipation of 200 W per board slot, there needs to be a mechanism for adequate cooling to prevent overheating and resulting failure of the devices and components of the system. The AdvancedTCA specification prescribes the rate of cooling air flow through partitions of the AdvancedTCA board and shelf sufficient to dissipate 200 W of power per board slot. In a typical implementation, blowers (i.e. mechanical fans) are provided in the shelf to pull air from front to rear and bottom to top. Thermal designs using mechanical fans are also typically encountered in enterprise class, rack mounted server blades. The standard cooling configuration in conventional rack mounted server blades is generally from front to rear and bottom to top in the manner specified for the AdvancedTCA shelf. In some instances, the rack in which the blades are housed is also tasked with generating and supplying the air flow.

Each of these approaches to cooling has several drawbacks. Notably, it assumes that cooling requirements for all boards are substantially equal, and that the airflow across all the boards is approximately equal. Furthermore, it does not consider “hot spots” on individual boards, but rather again uses an average airflow approach. In practice, the power consumption (and thus heat generation) within a typical ATCA chassis is uneven, with certain types of boards producing more heat that other types of boards. Furthermore, in many boards only a few components, such as processors, produce the majority of heat for the board. These components may become overheated if not provided with adequate airflow. Because the air flow is specified without factoring the location of the heat generating sources on the blade, it is often necessary to over-design the air flow generating elements which results in consumption of more-than-the-budgeted for power to drive the fans leaving less power for payload related operations. Moreover, power consumption is likely to migrate higher with increasing processor speed available to a server-blade based application. The limits of performance of the components in an ATCA blade may very well depend on its ability to dissipate the heat generated.

A circuit board may include an Intelligent Platform Management Controller (IPMC) that complies or is compatible with the Intelligent Platform Management Interface (IPMI) Standard detailed in “Intelligent Platform Management Interface Specification Second Generation,” Document Revision 1.0, dated Feb. 12, 2004, published by Intel, Hewlett-Packard, NEC, and Dell. The ATCA shelf may also include a shelf manager (hereinafter designated “ShMC”) to perform manageability functions for the shelf. Conventional shelf managers are typically implemented in software or firmware, or both. The shelf manager is typically capable of performing one or more manageability functions with respect to one or more elements populated on the shelf such as, for example, ATCA circuit cards, power modules, cooling units, field replaceable units and other resources and/or functionality of the shelf that are shared between all or a subset of the ATCA circuit boards. Typically the shelf manager communicates with one or more IPMCs comprised in one or more circuit boards. The shelf manager may reside on an ATCA circuit board that it manages or located in other circuit boards and/or other components populated on the shelf, or may be populated on shelf outside of the ATCA circuit boards or even lie external to the shelf.

The PICMG® Advanced Mezzanine Card (AdvancedMC or AMC) base specification, PIGMG AMC.0, Revision 1.0, published Jan. 3, 2005 (hereinafter referred to as the AMC.0 specification, the entire contents of which are incorporated herein by reference.) adds versatility to the modularity provided by the ATCA specification. The AMC specification defines the base-level mechanical, management, power, thermal, interconnect (including I/O) and system management requirements for hot-swappable, field-replaceable, add-on mezzanine cards (or modules) which may be hosted by an ATCA or a proprietary carrier board. Each AMC Module is received into an AMC Connector, seated parallel to the host carrier card and configured for high-speed, packet-based serial communications between the AMC card and the carrier board. There are six different form factors defined in the AMC specification which include two AMC module widths (W): the single width module (73.5 mm) and a double width module (148.5 mm); three heights (H) or thicknesses: compact (13.8 mm), mid-sized (18.96 mm) and full-sized (28.95 mm); and a single depth (D) (181.5 mm). The height (H) is measured in a direction normal to the major plane of the AMC card. The width (W) and height (H) dimensions lie along mutually perpendicular directions in a plane that is normal to the direction along which the depth (D) is measured. When the AMC module is mounted vertically, the width dimension is aligned vertically and the height or thickness dimension is aligned horizontally. The reverse is the case when the AMC module is mounted horizontally. Additionally, the AMC specification refers to three types of carrier board configurations—conventional, cutaway and hybrid.

The availability of AMC cards having a wide variety of form factors allows the cards to accommodate a rich mix of circuit elements and circuit topologies to support many different application architectures that can address the needs of diverse segments of the computer and telecommunications marketplace. The AMC architecture supports a number of transfer protocols with varying band widths as described in the subsidiary PICMG standard AMC3.0 for example. AMC cards extend the functionality of the ATCA carrier boards and permit multiple vendors to build technology solutions for transmission and switching equipment and allow these technology solutions to be used in multiple applications and in multiple vendor product lines. The ATCA standardization approach in general improves product reliability (allowing for industry standard hot swappable hardware and software, including power supplies and fans) and drives down prices—due in large part to greater economies of scale in manufacturing and less time spent on details standardized by ATCA (e.g., power, cooling, mechanical spacing and connectors issues).

Clearly, industry driven standards, such as the ATCA based standardization discussed above, allow performance-enhancing features and lower-cost assembly of systems. For example, in the case of the ATCA based standardization, the standard makes available standardized backplane, management functionality, power entry modules, cooling units and other modular components that are pluggable into a cost-reduced standardized-platform/chasses, prescribed by the standard, to deliver a user-configured solution in a logical package with lower component count and substantially simplified cabling and connectivity. However, technology implementations based on the ATCA specification represent “big iron” solutions that are suited to telephone company central offices with high density needs: i.e., switching systems and transmission cross connects. ATCA standardized chasses are too massive for remote/enterprise applications. Likewise, ATCA blades feature a form factor that makes them unsuitable for use in non-ATCA prescribed chasses such as the rack-mount chasses or shelf designed to be placed in the 19-inch standardized rack referenced above. It would be advantageous if the flexibility of a standards based architecture were made available in an enterprise class server blade offering.

### SUMMARY OF THE INVENTION

The present invention is directed to a standards-based server blade arrangement wherein individual circuit boards may be compliant with a first industry driven or other standard and housed within an enclosure configured such that one aspect of the enclosure provides each circuit board with a scalable, mechanical, electrical and environmental functionality required for that circuit board to comply with the first industry driven or other standard and a second aspect of the enclosure allows the enclosure to comply with a second industry driven or other standard.

In one of the several possible embodiments, the present invention provides a reconfigurable enclosure that complies with mechanical and electrical features that allow each circuit board, which may conform to a first industry standard, to be removably received within a separate portion of the enclosure and placed into interconnected electrical relationship with the other circuit boards such that the collection of interconnected circuit boards and the enclosure comprise a server blade arrangement compliant with a second industry standard with each separate portion of the enclosure providing the electrical, mechanical and environmental functionality required by the particular circuit board housed within it to be compliant with the particular industry standard associated with that circuit board.

In another embodiment, the present invention provides an enclosure substantially shaped and dimensioned into a server blade form factor capable of being removably received within a standardized 19″ rack or shelf. One aspect of this embodiment includes an enclosure that is generally rectangular shaped with one pair of opposed sides configured with respective a front opening and a rear opening. An intermediate plane is disposed within the enclosure and transverse to the opposed sides on which the front and rear openings are located. The first and second openings are configured for receiving there-through respective first and second circuit cards and placing the cards in sliding engagement on guideways in the enclosure for opposed movement towards and removable coupling with attachment points on the intermediate plane. In another aspect of this embodiment, the intermediate plane provides the infrastructure to electrically and mechanically couple the first and second circuit cards to each other and couple the server blade to other server blades within the rack.

In another embodiment of the present invention, there is provided an enclosure comprising a front portion, an intermediate portion and a rear portion wherein the front and rear portions are adapted to receive and house respective first and second circuit cards therein. The intermediate portion is adapted to releasably mate with said front and rear portions so that the front and rear portions extend in opposed directions from the intermediate portion. One feature of this embodiment provides for the intermediate portion to remain detachably attached to the rack while each of the front and rear portions is removably coupled to opposed portions of the intermediate portion such that the front portion, the intermediate portion and the rear portion cooperatively comprise an enclosure substantially shaped and dimensioned into a server blade form factor that is capable of being removably received within a standardized rack or shelf such as, for instance, a 19″ rack or shelf. Another aspect of this embodiment is that each of the front and rear portions may be hot-swapped without substantially interfering with the operation of the server blade.

In accordance with another embodiment of the present invention, the intermediate portion is configured as a passive connector module that provides mechanical connection points for releasably anchoring a first and opposed second carrier boards and electrical conduction paths to electrically couple the first and second carrier boards without materially changing the signals in any manner.

An object of embodiments of the present invention is to provide an enclosure that conforms to a standards compliant server blade form factor that is constructed to allow access to the internal cavity housing the circuitry and mechanical components during operation and without the need to interrupt operation of the server blade.

### BRIEF DESCRIPTION OF THE DRAWINGS

The invention may be more completely understood in consideration of the following detailed description of various embodiments of the invention in connection with the accompanying drawings, in which:

FIG. 1 is a perspective view of an exemplary modular chassis of the present invention.

FIG. 2 is a perspective view of an exemplary modular chassis according to a second embodiment of the present invention.

FIG. 3 is a perspective view of an exemplary modular chassis according to an alternate embodiment of the present invention

FIGS. 4 and 5 are exploded views of an exemplary chassis of the present invention.

FIG. 6 are the various views of the inner cover of the present invention

FIG. 7 illustrates various views of the strut of the present invention.

FIG. 8 are separate views of the cover of the present invention.

FIGS. 9 and 10 are a perspective view and front views of the ATCA carrier card used in conjunction with the present invention.

FIG. 11 shows an exemplary air flow path across the ATCA card when the card is installed within the chassis of the present invention.

FIG. 12 illustrates an exemplary faceplate of the present invention.

FIG. 13 is an illustration of an Electro static charge backer according to one embodiment of the present invention.

FIG. 14 is an exemplary embodiment of the mid-plane module of the present invention.

FIG. 15 illustrates assemblage of a mid-plane module and a front-side module of the present invention.

FIG. 16 is a functional block diagram illustrating an exemplary architecture of the chassis of the present invention wherein the chassis includes two ATCA cards.

FIG. 17 is a functional block diagram illustrating an exemplary architecture of the chassis of the present invention configured as a single board computer (SBC)

### DETAILED DESCRIPTION OF THE INVENTION

Reference will now be made to the figures with reference to which the various features of the present invention will be described in detail. The drawings are generally not to scale and the visual perception of the dimensions of the various elements from the various drawings and figures is not intended to limit the invention in any way. In general, the same reference numeral is used to refer to the same element illustrated in separate drawings and/or separate views. The following description provides numerous specific details of the present inventions are set forth in terms of descriptions of exemplary embodiments framed in the context of the ATCA standard. However, it will be understood that this approach does not limit the use of the principles and teachings disclosed herein to ATCA equipment. One skilled in the relevant art will recognize that the invention can be practiced without one or more of the specific details, or with other methods, components, materials, etc. In other instances, well-known structures, materials, or operations are not shown or described in detail to avoid obscuring aspects of the invention.

The following embodiments are merely illustrative of one possible type of modular electronic device. In general, the principles and teachings are applicable to various types of modular electronic equipment, including, but not limited to, telecommunications equipment, data communication equipment and computer equipment. Also, it is understood that the phraseology and terminology used herein are for the purpose of description and should not be regarded as limiting. The use herein of “including” and “comprising” and variations thereof is meant to encompass the items listed thereafter and equivalents thereof, as well as additional items and equivalents thereof. Furthermore, the term “connected” is used herein to denote a direct physical and/or mechanical connection between elements. The terms “coupled,” “operably coupled”, or “operably connected” as used herein signify an indirect connection between elements.

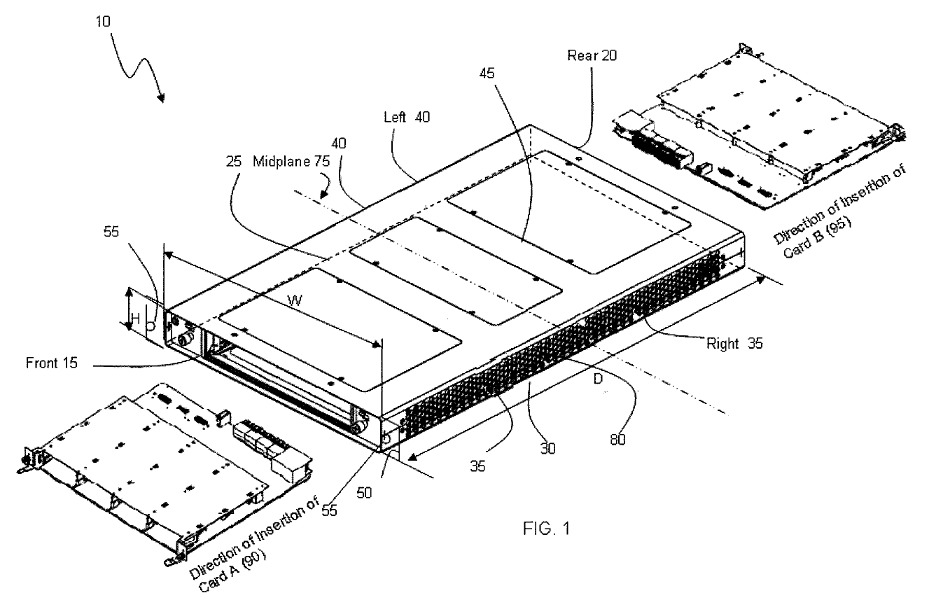

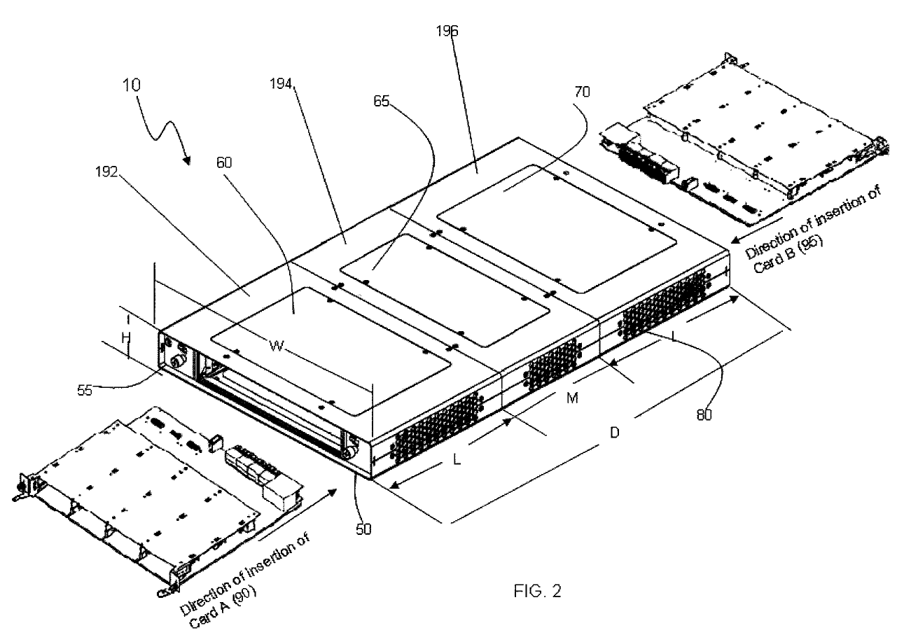

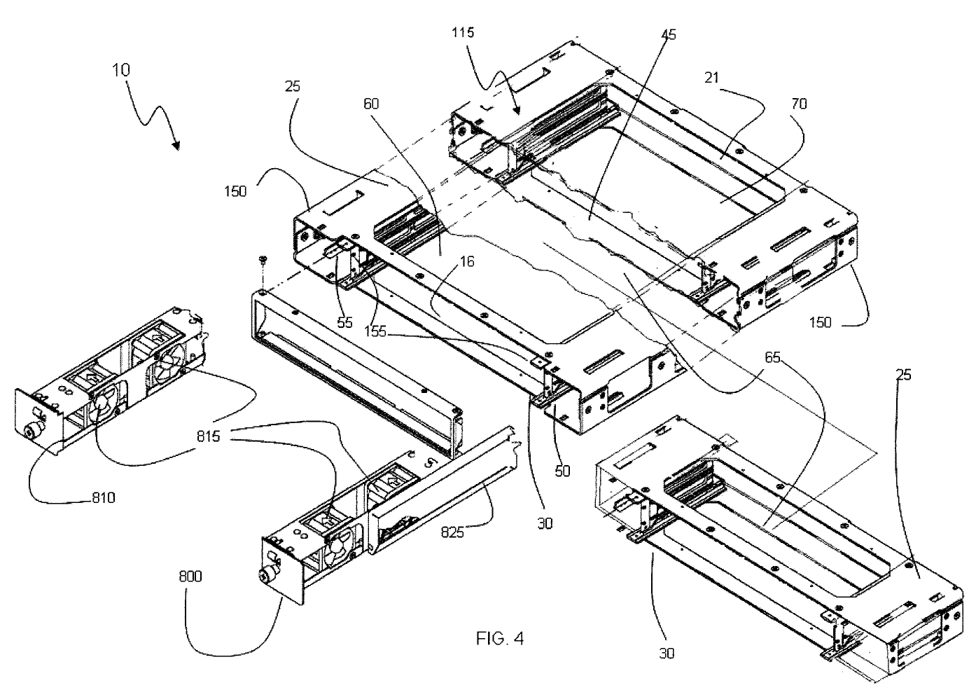

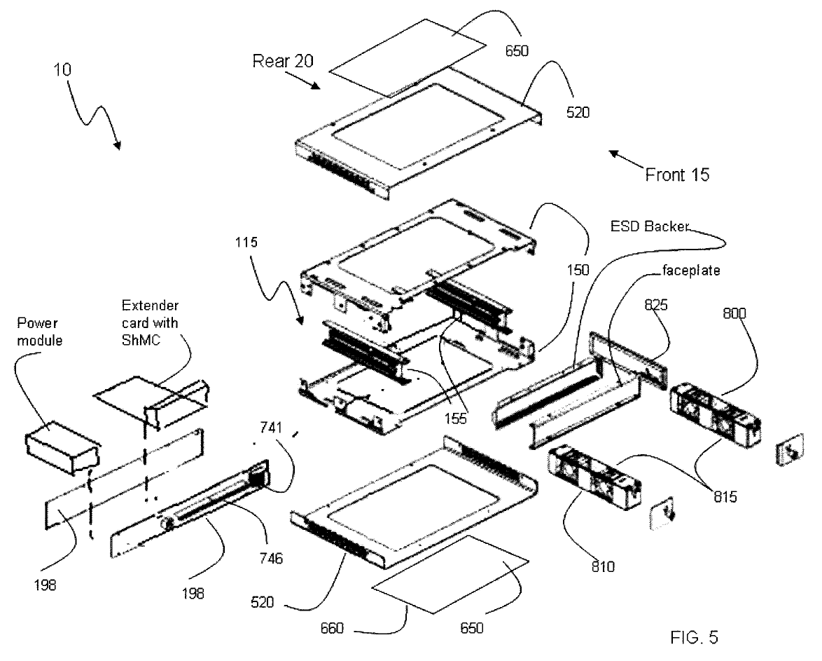

FIGS. 1, 2 and 3 are perspective views of a of modular chassis 10 (alternatively referred to as “blade”, “server blade”, “pizza-box”, “slab”, “enclosure”, “box”) providing the mechanical, electrical and environmental functionality required to house at least two operational ATCA cards according to one embodiment of the invention. FIGS. 4 and 5 are partial exploded views of the invention illustrated in FIGS. 1, 2 and 3. Referring now to FIGS. 1-5, the modular chassis 10 of the present invention has a front surface 15, a rear surface 20, a top wall 25, a bottom wall 30, right (left) side wall 35, and left (right) wall 40 that cooperatively enclose an interior region 45. Rack mounting flanges 50 with mounting holes 55 are provided on the right side wall and left side wall to allow the chassis and its contents to be mounted securely to a component rack using suitable fastening means. Alternately, chassis 10 may be slidingly engaged and supported on side rails on the rack via structural means provided on the right and left side walls (not illustrated) as is known in the art. Chassis 10 generally has an overall width W measured between the mounting holes 55, an overall height H between the top surface 25 and bottom surface 30, and an overall depth D measured between the front surface 15 and rear surface 20 as illustrated in FIGS. 1 and 2. In one embodiment of the present invention, depth D is generally about 30 to 33 inches. Various depths, such as, for example, 24, 36 and 48 inches may also be used within the scope of the present invention. Height H is desirably about 1.75 inches (or 1 U) and the width W is about 19 inches.

Interior region 45 is partitioned into a right-cooling unit portion 50, a left-cooling unit portion 55, a frontal portion 60, a mid-portion 65 and a rear portion 70 best illustrated in FIG. 4. Right-cooling unit portion 50 and left-cooling unit portion 55 extend longitudinally between the front surface 15 and rear surface 20 and are located adjacent right-side surface 35 and left-side surface 40 respectively. A mid-plane 75 is located substantially mid-way between the front surface 15 and rear surface 20 of chassis 10. Right-side wall 35 and left side wall 40 are each provided with a series of perforations 80 that place the interior region 45 in fluid communication with the environment external to the chassis 10. Frontal portion 60, mid-portion 65 and rear portion 70 are located within the interior region 45 in the volume and occupy the volume extending between right-cooling unit portion 50 and left-cooling unit portion 55. Frontal portion 60 is located proximate the front surface 15 and rear portion 70 is located proximate the rear surface 20 with the mid-portion 65 occupying the volume in between the two. As illustrated in FIG. 2, in the general embodiment of the present invention, the frontal portion 60 and the rear portion 70 are substantially similar in size and volume with each having a characteristic length L along the direction of depth D. Length L is determined by a longitudinal dimension of ATCA card 90 (95) as will be described in a following section. Mid-portion 65 is configured with a characteristic length M along the direction of depth D. Length M is adjustably sized such that the total length (L+M+L) is substantially the same as the depth D of chassis 10.

Referring now to FIGS. 4 and 5, FIG. 4 is a partially exploded view of chassis 10 depicting a skeleton frame assembly 115 that forms a basic building block of chassis 10 of the present invention. FIG. 5 is an exploded view of chassis 10 depicting the major components that comprise chassis 10. As illustrated in FIGS. 4 and 5, skeleton frame 115 preferably has a generally overall rectangular shape with a low profile and comprises a pair of inner covers 150 removably coupled to a pair of struts 155 by fasteners to form the interior region 45 appropriately partitioned into the right-cooling unit portion 50, the left-cooling unit portion 55, the frontal portion 60, the mid-portion 65 and the rear portion 70 as illustrated in FIG. 4. In other embodiments, the inner covers 150 and strut 155 can be secured by other appropriate securing methods well known to the art.

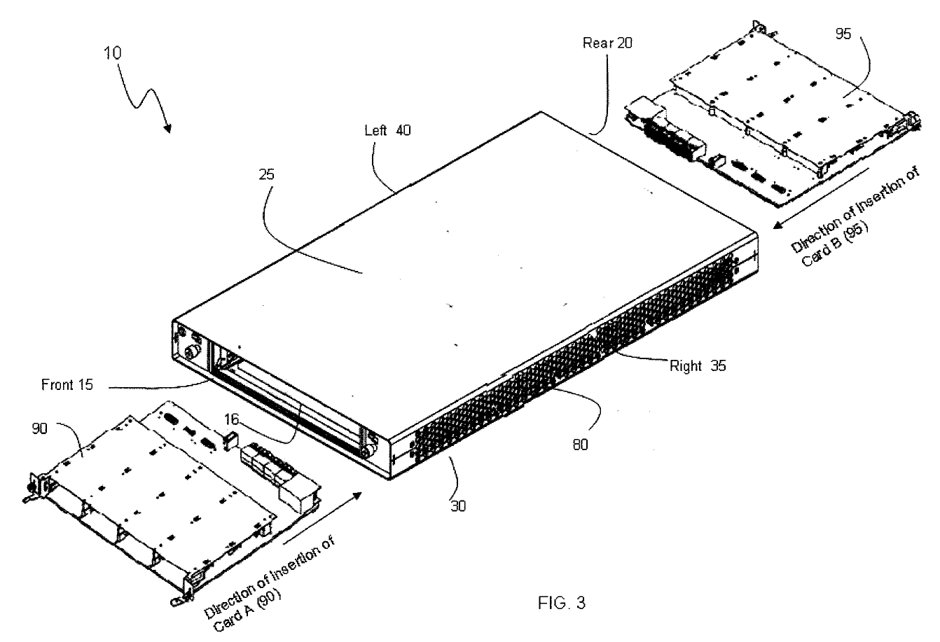

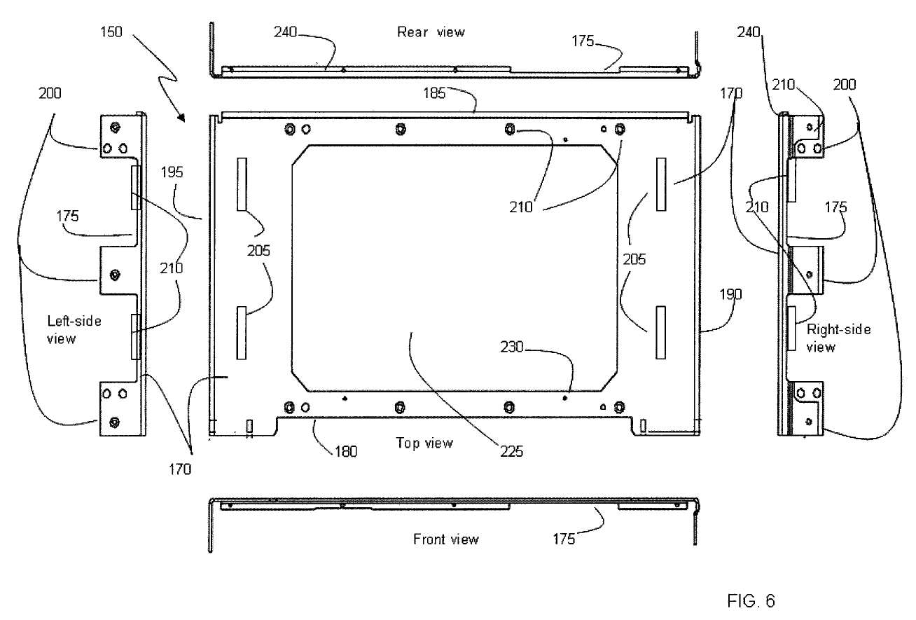

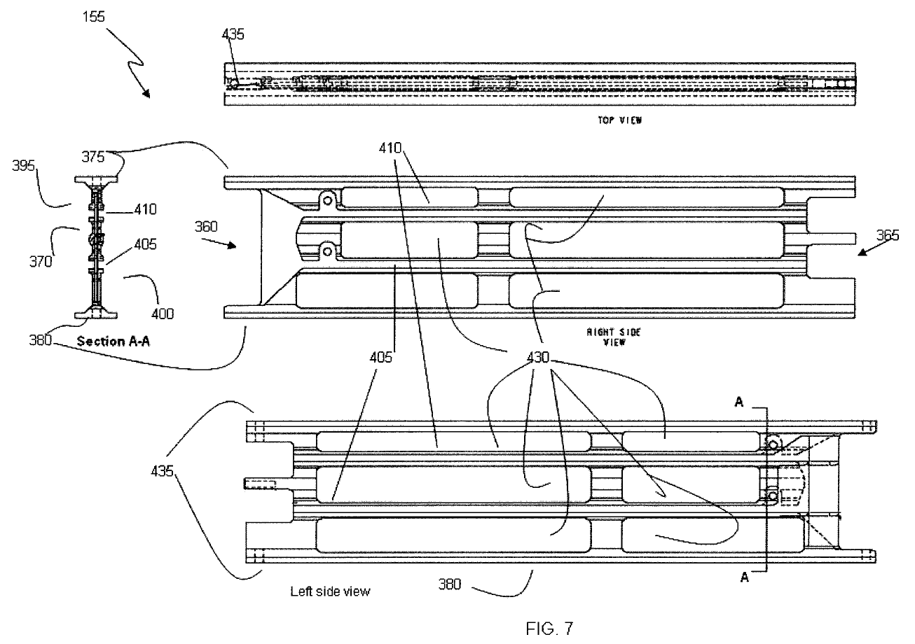

Reference is now made to FIGS. 5 and 6 wherein the inner cover 150 is illustrated. FIG. 6 shows the top view, right side view, left side view, front view and rear view of inner cover 150. Inner cover 150 is generally rectangular sheet-like or plate-like structure with a top surface 170 and an opposing bottom surface 175 extending between a first pair of opposed substantially parallel edges 180, 185 and a second pair of opposed substantially parallel edges 190, 195 as best illustrated in FIGS. 5 and 6. In one embodiment of the invention, edges 180, 185 are substantially perpendicular to edges 190, 195. Extending outwardly from each edge 190, 195 and substantially perpendicular to the top surface 170 are one or more first tabs 200. Inner cover 150 includes a groove 205 where a portion of the surface 170 is bent away from the top surface 170 towards the bottom surface 175 to project from the bottom surface 175 in the form of a guide tab 210. Guide tab 210 extends substantially parallel and adjacent to edges 190, 195 and is coplanar with tabs 200 as may be seen in FIGS. 6 and 7. Guide tab 110 serves to guide and locate a filter assembly within the chassis 10 as will be explained in a later section. Inner cover 150 is provided with a first set of apertures 215 through which fasteners can be inserted. Each tab 200 also includes a structure defining at least one hole 220 for receiving a fastener. The hole 220 can be a through hole, a threaded hole, a blind hole or other construction to accommodate fasteners such as for instance, a screw, a nut and bolt, a rivet or other fasteners without falling outside the scope of the invention. To access the interior region 45, a central portion of the inner cover 50 is formed as an opening 225 defined by a rim 230 and having a first area extent 235. In one embodiment illustrated in FIG. 3, the opening 225 is omitted. In another embodiment illustrated in FIG. 1, the opening 225 comprises a plurality of openings to maintain the structural stiffness of inner cover 150 against excessive flexing. In one embodiment of the present invention, structural features on inner cover 150, such as the size, number and location of first tabs 200, groove 205, guide tab 210, apertures 215, hole 220, opening 225 and rim 230 are symmetric about a plane perpendicular to the top surface 170 (and bottom surface 175) and parallel to edges 190, 195 and a plane perpendicular to the top surface 170 and parallel to edges 180, 185.

In the embodiment illustrated in FIG. 2, chassis 10 is an assembly of three separate structural modules 192, 194 and 196. Each structural module 192, 194 and 196 has a structural construction that utilizes the basis building block comprising the skeleton frame assembly 115 described in this section and assembled into a monolithic chassis 10 as illustrated in FIG. 2. In such instances, modules 192 and 196 are assembled with their edges 185 abutting intermediate module 194. Furthermore, edge 185 of modules 192 and 196 and both edges 180 and 185 of intermediate module 194 may be provided with a plurality of attachment tabs 240 that extend perpendicular to bottom surface 175 and away from the top surface 170 to provide a point of attachment for locating and securing backplanes 198 to chassis 10 as may be understood from the illustration of FIGS. 5 and 6. Inner cover 50 can be made of any suitable material such as aluminum, steel, and other material which material may be shaped using a process such as forming, drawing or other suitable processes well known in the art. It is understood that the scope of the present invention is not limited by either the materials of construction or mode of fabrication of the constituent components of the chassis.

One embodiment of strut 155 will now be described with reference to FIGS. 5, 7. FIG. 7 depicts the top view, right side view, left side view and sectional view of strut 155. Strut 155 is a longitudinal member of length SL (not illustrated) extending between a beam-front end 360 and beam-rear end 365. Strut 55 has a I-shaped cross-section 370 extending between a strut top surface 375 and an opposed strut bottom surface 380 of height SH (not illustrated) to form a card guide assembly best depicted in the illustration of FIG. 7. I-shaped cross-section 370 has a width SW (not illustrated) transverse to height SH. Width SW has a left-side lateral surface 395 opposite a right-side lateral surface 400 best seen in the illustration of FIG. 7. Lateral surfaces 390 and 395 are provided with first opposed longitudinal card-guides 405 and second opposed longitudinal card-guides 410, extending along the length SL, disposed at a first height 415 (not illustrated) and a second height 420 (not illustrated) respectively from the bottom surface 380 such that card-guides 410 are proximate the strut top surface 275. Height SH is determinative of the total height of the chassis 10 and a maximum height of ATCA card modules 90(95) that may be housed within the chassis 10. Height 415 of opposed card guides 405 is selected to receive and guide the ATCA card 90 (95) having a height dimension that is less than or equal to the maximum height as defined by the ATCA specification as will be described in the following sections. I-shaped cross-section 370 has a structure defining a plurality of cross-section apertures 430 for placing the lateral surfaces 390 and 400 in fluid communication with each other. Top and bottom surfaces 375 and 380 are provided with attachment-apertures 435 sized and located to allow strut 155 to be mated to inner cover 150 using a fastener or other suitable fastening method to form the skeleton frame 115 as will be described in the following sections. Strut 155 is typically an extrusion of aluminum so as to impart structural rigidity and light weight to the strut. However, any other manufacturing process and material known to the art can be used without digressing from the scope of the present invention.

In one embodiment, strut 155 may also provide structural attachment points (not shown) to precisely locate and mount one or more of the backplanes 198, an extender card (alternatively midplane) 510, power modules 515 and shelf manager module 520 within the interior region 45 substantially proximate or within mid-portion 65 as will be described in the following sections. In alternate embodiments, guide channels may be formed on inner cover surfaces to slidingly receive and guide the strut 155 within the skeleton frame. Strut 155 provides structural support for the chassis 10 and the components installed within chassis 10. Strut 155 also provides a datum for the ATCA carrier cards and the backplanes mated to the ATCA carrier cards. Strut 155 thereby serves to position the backplanes 198 and the card guides 405 and 410 in precise geometrical relationship so that when the carrier cards 90(95) are installed within chassis 10, connectors 740, 745 and others present on the carrier card edge 710 are always positioned in aligned relationship with their counterparts on the backplane 198 to enable repeatable and error-free mating during the installation of ATCA carrier cards 90 (95) within chassis 10.

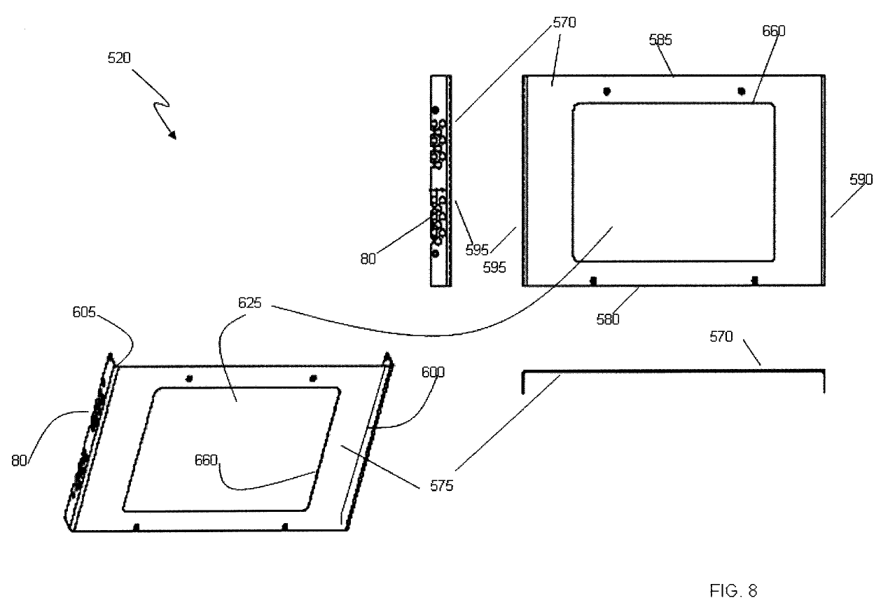

As illustrated in FIGS. 5 and 8, in one embodiment the chassis 10 includes a generally C-shaped cover 520 having a generally rectangular sheet-like or plate-like structure with a cover-top surface 570 and an opposing cover-bottom surface 575 extending between a first pair of opposed substantially parallel edges 580, 585 and a second pair of opposed substantially parallel edges 590, 595. Projecting downwardly from edges 590 and 595 are side walls 600 and 605 respectively. Each side wall 600, 605 has disposed on it a plurality of perforations 80 sized and shaped to allow air flow there-through and prevent electromagnetic radiation from escaping from the interior region 45 when the chassis 10 is in operation. Cover 520 is provided with a plurality of cover-apertures 515 through which fasteners can be inserted. To facilitate access to the interior chamber 45, a central portion of the cover 520 is formed as a cover opening 625 defined by a cover rim 630 and having a second area extent 635 (not illustrated). Cover opening 625 has a shape that is substantially identical to the shape of opening 225 on inner cover 150 but the area 635 is proportionally larger than area 235. Cover 520, including the structural features associated with cover 520, is symmetric about a plane perpendicular to the cover-top surface 570 and parallel to edges 580, 585 as well as about a plane perpendicular to the cover-top surface 570 and parallel to edges 590, 595.

In one embodiment of the present invention, cover 520 is placed over inner cover 150 of the skeleton frame 115 with edges 580, 585, 590 and 595 of cover 520 being in substantial parallel alignment with edges 180, 185, 190 and 195 of inner cover 150. Cover 520 is shaped and dimensioned such that cover-bottom surface 575 substantially conforms to a portion of the inner cover 150 such that at least one cover-aperture 515 is in substantial alignment with hole 220 on tab 200 so that a fastener can be inserted through each corresponding cover aperture 515 and hole 220 to releaseably fasten cover 520 to inner cover 150 of skeleton frame 115 as best illustrated in FIG. 1-5. In this configuration, cover opening 625 is concentrically located with opening 225 with cover rim 630 disposed around and outward of rim 230 so as to form a ledge 645 extending between the two rims. Access panel 650, depicted in FIG. 5, is a flat sheet-like structure with a peripheral edge 660 that is shaped and dimensioned to substantially conform to the rim 630. In practice, access panel 650 is supported on the ledge 645 extending between the cover-rim 630 and rim 230 on inner cover 150 so that peripheral edge 660 is located adjacent to cover rim 630 and the cover opening 625 is substantially covered. Access panel 650 is removably fastened to the inner cover 150 using fasteners inserted through access panel apertures 665 on access panel 650 that align with suitably disposed apertures 225 on inner cover 150 when access panel 650 is located on ledge 645. In this configuration, access panel 650 encloses interior region 45 housing ATCA card modules according to the present invention. Upon removal of access panel 650, access is obtained to the electrical components inside the interior chamber 45 for testing and probing the components on the ATCA carrier card or other module housed within the interior chamber 45 but without interrupting the operation of the other modules.

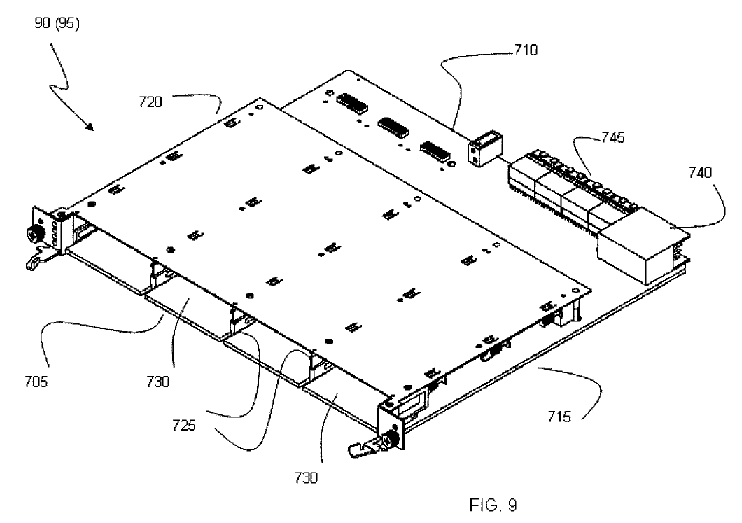

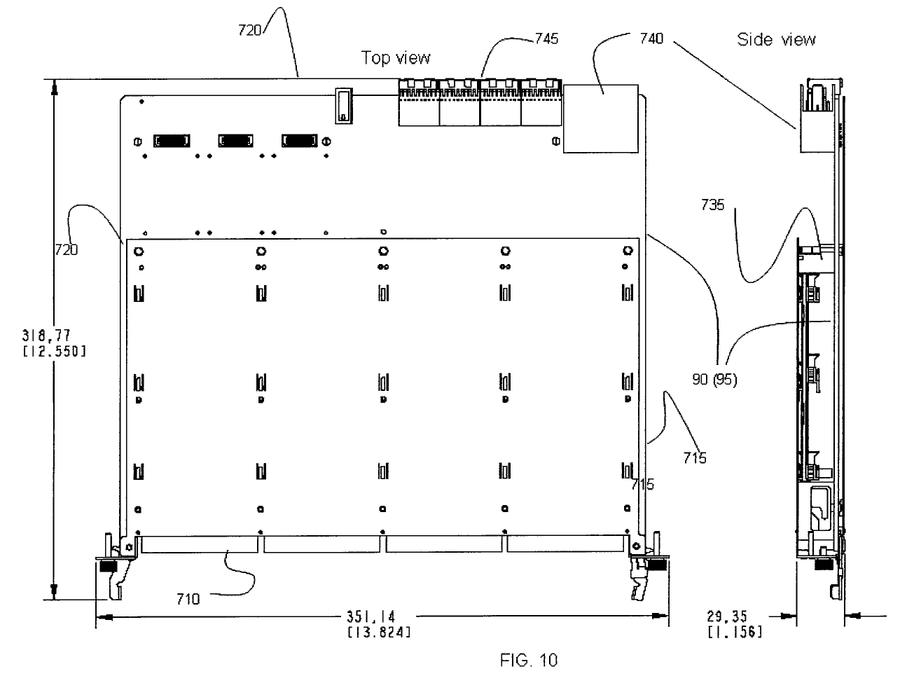

As depicted in FIGS. 1, 2, and 3, skeleton frame 115, including the inner covers 150 and struts 155, the covers 520, and backplane 198, defines an enclosure suitable for receiving ATCA cards. One of skill in the art will readily recognize that the exemplary construction of chassis 10 described above provides a relatively light-weight but sufficiently rigid structure capable of supporting its own weight and the weight of the ATCA cards housed therein without substantial deformation or distortion of the precise dimensional relationships between the various components of the structure. These characteristics allow the modular chassis 10 to be inserted into, and removed from the rack and generally handled as a single server blade unit while maintaining the at least two operational ATCA cards housed within the chassis 10 in the prescribed mechanical, electrical and functional relationship relative to each other and relative to the chassis. FIGS. 9 and 10 depict an exemplary ATCA carrier board that (also referred to as simply ATCA boards) configured to be installed in an ATCA chassis, i.e. a chassis or enclosure that is designed to removably receive at least one ATCA Carrier card. FIG. 10 shows a top view and a side view of the ATCA carrier board 90 (95). The ATCA carrier board 90 (95) illustrated in FIG. 9 includes a printed circuit board (PCB) 700 with a PCB front edge 705, a PCB rear edge 710 and PCB parallel side edges 715, 720 extending between PCB front edge 705 and PCB rear edge 710. Guide rails 725 are configured on the PCB 700 to slidingly receive a plurality of AdvancedMC (AMC) modules (not shown) within bays 730 for mating with AMC connectors 735 on ATCA carrier board 90 (95). It will be appreciated that ATCA carrier board 90 (95) also includes a power connector 740 via which power is provided to the carrier board from an ATCA chassis backplane, and various input/output (I/O) connectors 745 via which signals are routed to the backplane 198, and hence to other ATCA boards and/or AdvancedMC modules (mounted to other ATCA carrier boards) that are similarly coupled to the ATCA backplane 198. Front surface 15 of chassis 10 defines a front opening 16 and rear surface 20 of chassis 10 defines a rear opening 21 disposed in opposing relationship with front opening 16. Edge 720 of ATCA carrier board 90 (95) is positionable within opening 16 (21) with the longitudinal edges 715, 720 being slidingly received within longitudinal card-guides 405 of the pair of struts 155 best illustrated in FIGS. 3, 4 and 5. Longitudinal card-guides 405 guide and support the carrier board 90 (95) as it is progressively inserted within frontal portion 60 (rear portion 70) until it is installed within interior region 45 of chassis 10. Backplane 198, illustrated in FIG. 5, is equipped with connectors power connector 741 and I/O connectors 746 configured to mate with power connectors 740 and I/O connectors 740 when ATCA carrier board 90 (95) is fully installed within chassis 10. One of skill in the art will readily recognize from FIGS. 2 and 10, that when fully installed within interior region 45, each ATCA carrier board 90 (95) will populate the interior of front portion 60 (rear portion 70) of interior region 45. Consequently, the dimension L depicted in FIG. 2 will be at least about 12.550 inches whereby dimension M, depicted in the same figure, will be about 5 inches.

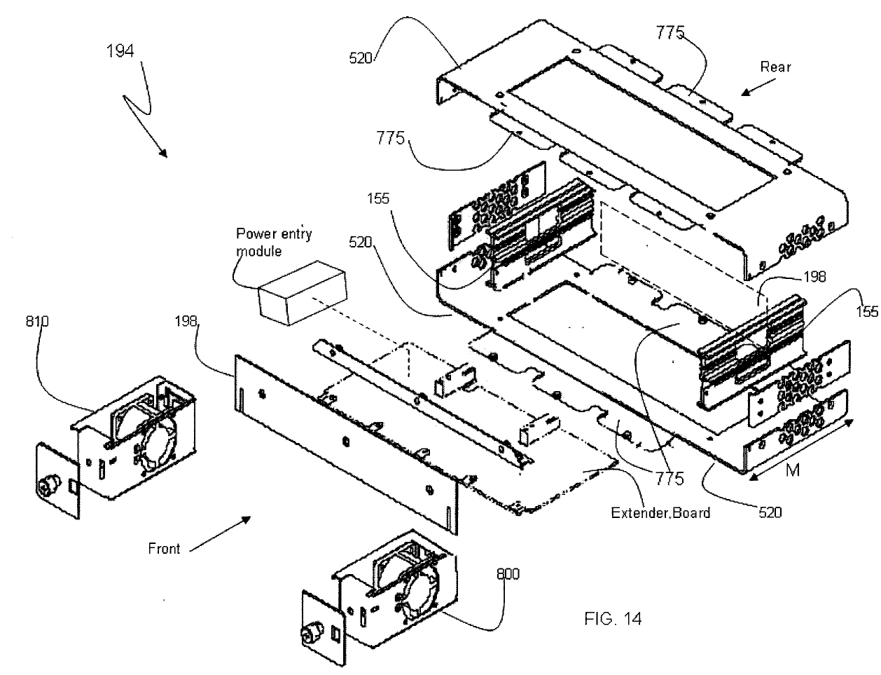

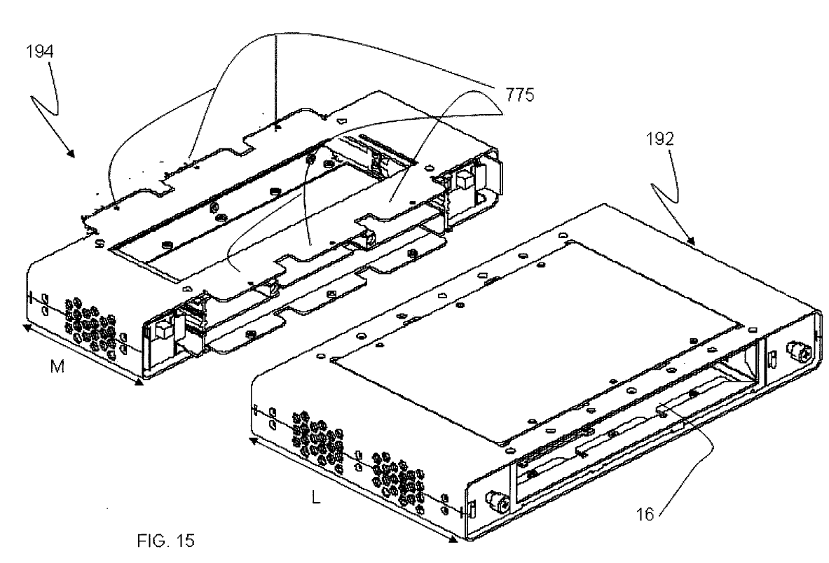

Referring to FIGS. 2, 14 and 15, there is depicted an alternate embodiment of the present invention wherein three separate modules 192, 194 and 196 are releasably secured to form the chassis 10 by means of coupling tabs 775. FIG. 14 is an exploded view of mid-plane module 194. Each of modules 192 and 196 may be field replaceable units (FRUs) allowing quick swapping of the entire unit when desired. However, in the embodiment of the present invention illustrated in FIGS. 1 and 3, for example, the ATCA carrier cards 90 (95) are FRUs, while the rest of the physical framework remains on the rack as part of the blade or chassis 10.

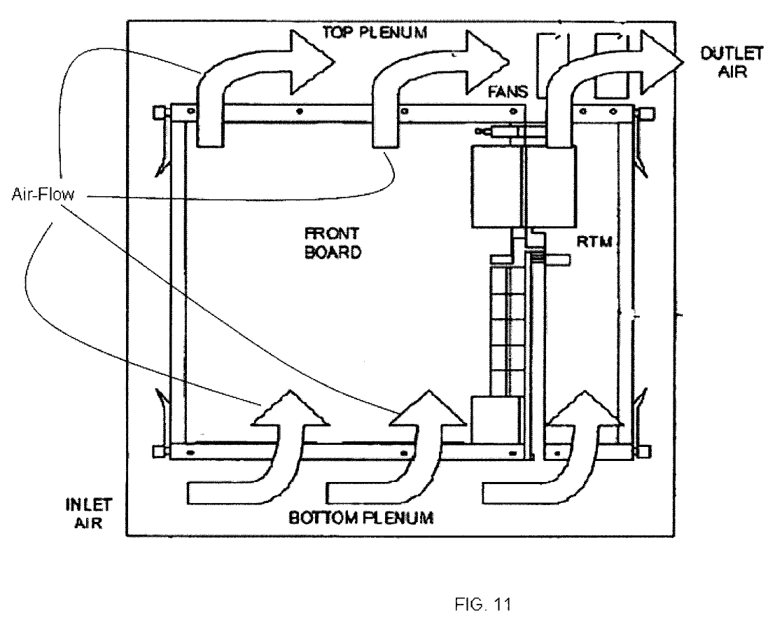

FIG. 11 illustrates the ATCA standards specified air-flow over various regions of the ATCA carrier card 90 (95). In the present invention, right-cooling unit portion 50 and left-cooling unit portion 55 are each provided with cooling units 800 and 810 respectively as best seen in the illustration of FIG. 4. Each cooling unit comprises cooling fans 815 that take in air and blow it. Cooling unit 800 may pull in air from the external environment through perforations 80 on right-side wall 35 and blow it into interior region 45 and over ATCA board 90 (95). A filter 825 is disposed between right-side wall 35 and the cooling unit 800 to filter air as it enters into the chassis 10. Cooling unit 810 adjacent left-side wall 40 may then push the air from the interior region 45 to the external environment through perforations 80 on left-side wall 40. The push-pull air moving units 800, 810 are FRUs. Together, the air moving units 800 and 810 maintain the air flow profile substantially as required by the ATCA specification and illustrated in FIG. 11.

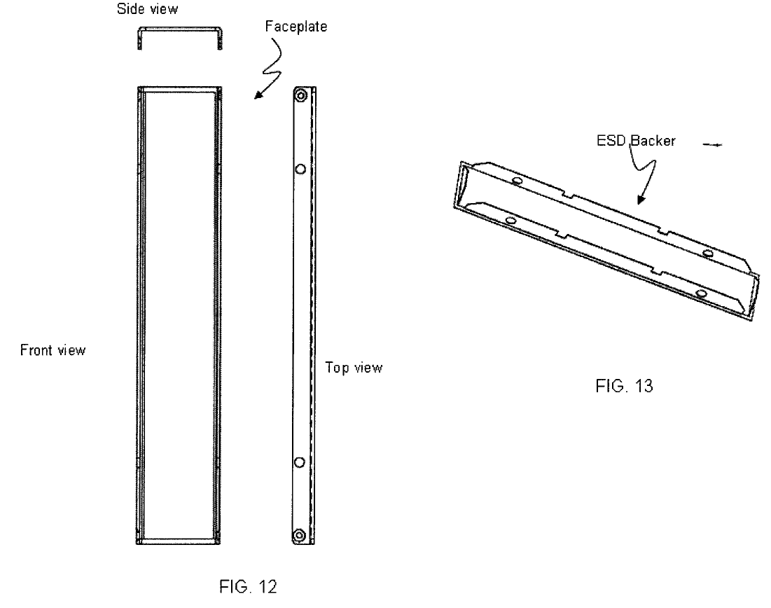

FIGS. 12 and 13 depict the faceplate and ESD backer plate that may be mounted on the periphery of front opening 16 and rear opening 21 to prevent EMI discharge from leaking from the chassis 10 when all the ATCA modules 95 (98) are populated into chassis 10. In instances where one or more cards or mezzanine cards (i.e. AMC cards) are not installed on chassis 10, a dummy card of the same form factor as the card that is not installed is installed in place of the card that is missing. This arrangement serves to prevent air flow and EMI leaks from the chassis 10 to the external environment. It will be noted that in this embodiment the filter assembly is mounted adjacent a side wall (i.e. either the right or the left side wall) through which air intake into the interior region 45 takes place.

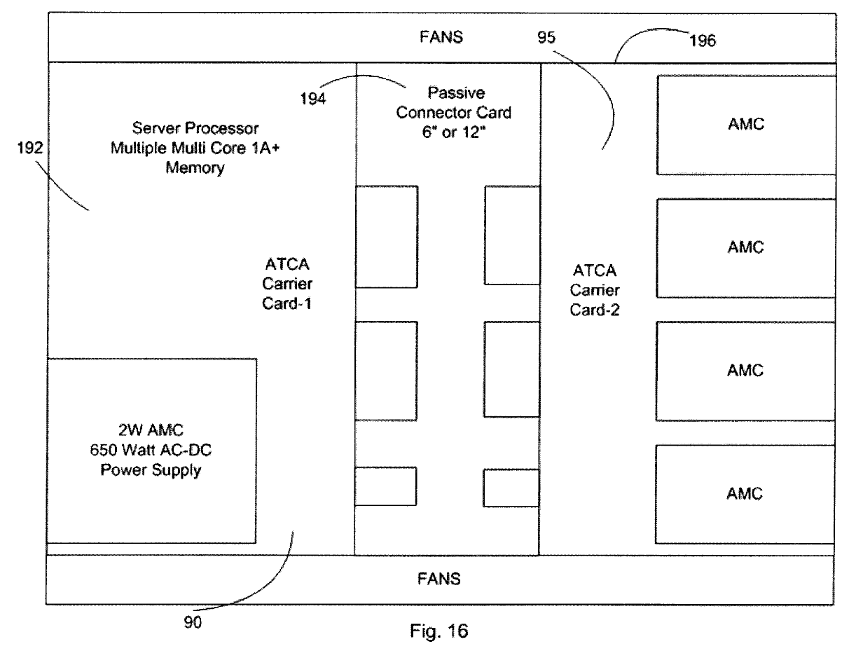

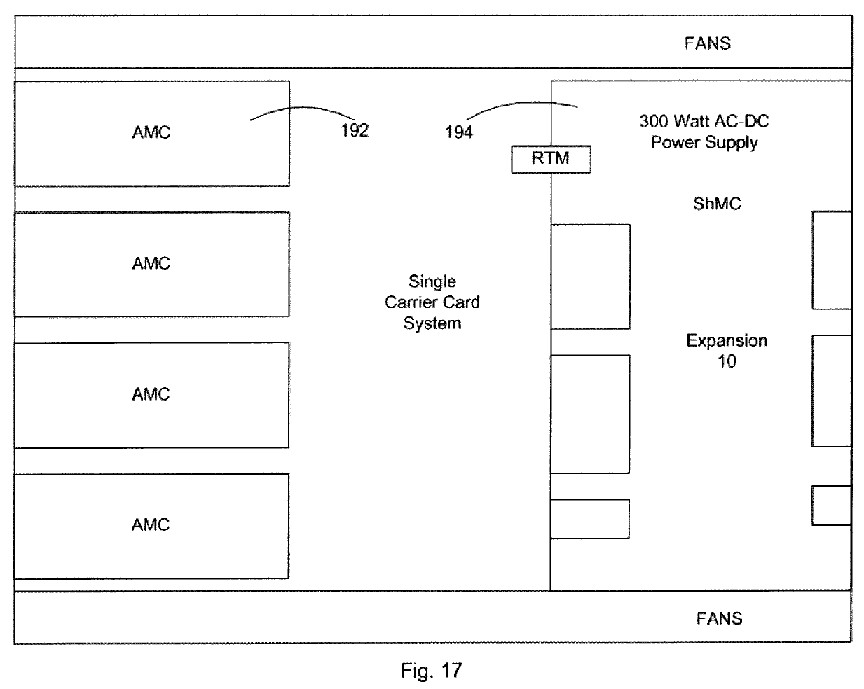

FIGS. 16 and 17 are functional block diagrams of the chassis 10 of embodiments of the present invention. The exemplary embodiment illustrated in FIG. 16 includes an ATCA carrier card 90 architected to comprise a server processor, such as a multi-multiple core Intel Architecture (IA) processor and associated memory, and an AC-DC power supply, such as the 2 W AMC 650 Watt AC-DC Power Supply available from CorEdge Networks, the assignee of the present application. ATCA carrier card 95 is coupled to a plurality of mezzanine cards (such as for example, AMC modules), which expand the functionality of the ATCA Carrier card 95. AMC cards present I/O interfaces that may enable data communication to and from chassis 10. In this embodiment, mid-plane module 194 is configured to provide the functionally of a passive connector that is operative to couple the backplanes 198 associated with each of the front and rear portions 192 and 196 respectively of the chassis 10. Coupling backplanes 198 effectively interconnects the ATCA cards 90 and 95 installed within front and rear portions 192 and 196 of chassis 10.

It will be appreciated that other ATCA-standard compliant architectures are also possible within the scope of the present invention. For example, the power module may be located within the mid-plane module 194 and connected to an external AC or DC power source via power rails that are ducted from the rear of the chassis 10 through interior region 45 and into the mid-plane region 194. Power from the power module is then provided to each of the power connectors on the individual ATCA carrier cards 90 (95) via the backplane and through the power connectors on the backplane that interconnect with the power connectors on the ATCA carrier cards when the cards are installed within chassis 10.

It must be emphasized that ATCA carrier cards are used for ease of description but not by way of limitation. The modular structure of the present invention allows for reconfiguring chassis 10 to be capable of accommodating circuit boards that comply with standards other than the ATCA specification with the mid-plane module providing the electrical and mechanical functionality to allow the circuit boards to interoperate within the chassis and within the rack in which the chassis is mounted. In alternate embodiments, the mid-plane module cooperates with one of the two circuit boards to provide appropriate electrical, mechanical and environmental functionality required for the proper operation of the other of the two circuit boards. In yet another embodiment of the present invention, one or more of the server blades in a rack may be specialized to deploy the electrical functionality—such as the power, fabric lanes, management and control to the remaining server blades in the rack.

Another feature of embodiments of the present invention is that a shelf manager may be advantageously housed within the extents of the mid-plane module 194 or optionally, the shelf manager implemented in firmware, may be located on one of the mezzanine cards. FIG. 17 illustrates another exemplary embodiment of the present invention. In FIG. 17, there is depicted an ATCA carrier card 190 architecture that includes a plurality of mezzanine cards (for instance, AMC cards) associated with the ATCA carrier card 90. The mid-plane module 194 houses a power supply, a shelf manager and an expansion I/O arrangement. The power supply may be, for example, a 300 Watt AC-DC power supply available from CorEdge Networks, to whom the present invention is assigned. Thus configured, ATCA carrier card 90 is operative as a single board computer. In this embodiment, the second ATCA carrier card 196 need not be used. Instead, a dummy mechanical card having the same form factor as the carrier card 95 is inserted into chassis 10 to prevent air-flow and EMI leakage from the interior region 45.

In alternate embodiments, ATCA carrier card 95 is installed within chassis 10 but is configured to operate independently of ATCA carrier card 90 (i.e. the single board computer) while obtaining power and shelf manager services from the common resources housed within, the mid-plane module 194. In another embodiment, carrier card 95 may interconnect with carrier card 90 via the mid-place module 194. In this instance, carrier card 95 may function as a companion to carrier card 90 by supporting one or more storage devices and other peripherals via the use of mezzanine cards, for example, interconnecting with the carrier card 90 to provide RAID functionality to it. In another embodiment, several chassis 10 may be supported in a rack in stacked and interconnected relationship to each other. It will be appreciated that numerous other applications are possible using chassis 10 without deviating from the scope of the present invention. In one embodiment, the present invention provides a modular, scalable, highly reliable, readily reconfigurable, standards-based server blade system.

While the invention is amenable to various modifications and alternative forms, specifics thereof have been shown by way of example in the drawings and described in detail. It should be understood, however, that the intention is not to limit the invention to the particular embodiments described. On the contrary, the intention is to cover all modifications, equivalents, and alternatives falling within the spirit and scope of the invention as defined by the appended claims.

1. A server chassis comprising:
an enclosure having an exterior forming a first external shape bounding an internal cavity, the internal cavity presenting first and second opposed openings extending substantially in a first direction and communicating the internal cavity to the exterior of the enclosure;
an intermediate plane disposed in the internal cavity and extending substantially transverse to the first direction, the intermediate plane including connection points and electrical circuitry;
first and second circuit cards configured for insertion into said first and second opposed openings and removably attached to the intermediate plane at said connection points and placed in electrical relationship through the intermediation of said electrical circuitry; and
at least one cooling unit disposed within said internal cavity for providing a standards defined cooling to said first and second circuit boards.

2. A reconfigurable server chassis comprising:
a reconfigurable enclosure that includes reconfigurable elements adapted to selectably comply with mechanical and electrical features to house in a first portion of the enclosure a plurality of first circuit boards provided in accordance with a first industry standard for mechanical and electrical requirements and to house in a second portion of the enclosure a plurality of second circuit boards provided in accordance with a second industry standard for mechanical and electrical requirements;
mechanical and electrical elements provided with the enclosure and adapted to electrically interconnect at least one of the first circuit boards with at least one of the second circuit boards; and
first and second environmental control elements operatively controlling an environmental functionality as required by the circuit boards housed in the corresponding one of the first and second portions of the enclosure.

3. A circuit board enclosure arrangement comprising:
a front housing portion and a rear housing portion, each housing portion including structure adapted to receive and house first and second circuit cards respectively therein; and
an intermediate portion defined between the front housing portion and the rear housing portion and adapted to releasably mate with the front housing portion and the rear housing portion such that the front housing portion and the rear housing portion extend in opposed directions from the intermediate portion, the intermediate portion including structure providing electrical interconnection between the first and second circuit cards.
